(19) United States
(12) Patent Application Publication
(10) Pub. No.: US 2025/0063690 A1
(43) Pub. Date: Feb. 20, 2025

(54) HEAT-PUMP HEAT SOURCE APPARATUS

(71) Applicant: Mitsubishi Electric Corporation, Tokyo (JP)

(72) Inventors: Naoto ISHII, Tokyo (JP); Akinori KURACHI, Tokyo (JP); Kimitaka KADOWAKI, Tokyo (JP)

(21) Appl. No.: 18/724,920

(22) PCT Filed: Mar. 18, 2022
(86) PCT No.: PCT/JP2022/012622

§ 371 Date: Jun. 27, 2024

(51) Int. Cl. H05K 7/20; F24F 11/88

(52) U.S. Cl. CPC H05K 7/20272; F24F 11/88

(57) ABSTRACT

A heat-pump heat source apparatus includes: a housing including a bottom plate; a water pump box provided on a front side of the bottom plate, the water pump accommodating a water pump; a transformer box provided above the water pump box, the transformer box accommodating a transformer; and a controller box provided above the transformer box, the controller accommodating a controller.

### CROSS-REFERENCE TO RELATED APPLICATION

This application is a U.S. national stage application of PCT/JP2022/012622 filed on Mar. 18, 2022, the contents of which are incorporated herein by reference.

### TECHNICAL FIELD The present disclosure relates to a heat-pump heat source apparatus to be used in a water heating or cooling device such as a chiller or a water heater.

### BACKGROUND

Heat-pump refrigeration cycle apparatuses such as an air-conditioning apparatus, a chiller, and a water heater include a heat-pump refrigeration cycle apparatus in which a transformer is accommodated in a box, and the box is provided along with a compressor, a heat exchanger, a controller, and other devices, in a housing of a heat source apparatus. For example, in a refrigeration cycle device described in Patent Literature 1, a transformer is accommodated in a storage box, and the storage box and a controller are provided on a bottom plate of an outdoor unit that is a heat source apparatus.

### PATENT LITERATURE

Patent Literature 1: Japanese Unexamined Patent Application Publication No. 2017-166756

As disclosed in Patent Literature 1, in the case where electrical components such as the transformer and a reactor are accommodated in the storage box, the storage box may be provided on the bottom plate of the housing of the heat source apparatus from the viewpoint of maintainability and the balancing regarding the center of gravity of the housing. Furthermore, in some heat-pump chillers and water heaters, a water pump is located in the housing of the heat source apparatus. In other words, the storage box that accommodates electronic components such as the transformer may be accommodated along with the water pump in a single housing. However, in the case where the storage box and the controller are provided on the bottom plate of the heat source apparatus, if water leaks from the water pump in the housing of the heat source unit, there is a risk that the electronic components in the storage box and the controller may be submerged or immersed in the water.

### SUMMARY

The present disclosure is applied to solve the above problem, and relates to a heat-pump heat source apparatus that can prevent, if a water leak occurs in the housing thereof, a transformer and a controller from being submerged or immersed in water.

A heat-pump heat source apparatus according to an embodiment of the present disclosure includes: a housing including a bottom plate; a water pump box provided on a front side of the bottom plate, the water pump accommodating a water pump; a transformer box provided above the water pump box, the transformer box accommodating a transformer; and a controller box provided above the transformer box, the controller accommodating a controller.

According to the embodiment of the present disclosure, the water pump box that accommodates the water pump is provided on the bottom plate of the housing of the heat source apparatus. The transformer box that accommodates the transformer is provided above the water pump box. Furthermore, the controller box that accommodates the controller is provided above the transformer box. The transformer and the controller are provided above the water pump box, not on the bottom plate of the housing of the heat source apparatus. Therefore, if a water leak occurs in the housing of the heat source apparatus, the controller and the transformer are prevented from being submerged or immersed in water.

### BRIEF DESCRIPTION OF DRAWINGS

FIG. 1 is a circuit diagram illustrating a configuration of a heat-pump heat source apparatus according to an embodiment.

FIG. 2 is a perspective view illustrating an internal configuration of the heat-pump heat source apparatus according to the embodiment.

FIG. 3 is a perspective view illustrating an installation configuration of a water pump box, a transformer box, and a controller box according to the embodiment.

FIG. 4 is an exploded perspective view for explanation of a configuration of the water pump box and the transformer box according to the embodiment.

FIG. 5 is an explanatory view for the procedure of removal of the transformer box.

FIG. 6 is a perspective view for explanation the arrangement of a plurality of transformers according to the embodiment.

FIG. 7 is a perspective view illustrating an internal configuration of the transformer box according to the embodiment.

FIG. 8 is a plan view of the transformer box that is in a state illustrated in FIG. 7.

FIG. 9 is a front view of the transformer box that is in the state illustrated in FIG. 7.

FIG. 10 is a transparent side view of the transformer box that is in the state illustrated in FIG. 7.

FIG. 11 is a plan view illustrating bundling of wires in the transformer box according to the embodiment.

FIG. 12 is a front view illustrating bundling of the wires in the transformer box according to the embodiment.

### DETAILED DESCRIPTION

A heat-pump heat source apparatus according to an embodiment of the present disclosure will be described with reference to the drawings. The present disclosure is not limited to the embodiment described below, and various modifications can be made without departing from the gist of the present disclosure. In addition, the present disclosure encompasses all combinations of combinable ones of configurations described below with respect to the embodiment. In each of figures in the drawings, components that are the same as or equivalent to those in a previous figure or previous figures are denoted by the same reference signs. The same is true of the entire text of the specification. It should be noted that in the figures, relationships in relative size between components and the sizes of the components may differ from those of actual ones.

In the figures that will be referred to below, an X direction indicates a lateral direction of the heat-pump heat source apparatus, and is a direction from the right side to the left side as indicated by an X arrow. A Y direction is a front-back direction of the heat-pump heat source apparatus, and is a direction from the front side to the back side as indicated by a Y arrow. A Z direction is an up-down direction of the heat-pump heat source apparatus, and is a direction from the lower side to the upper side as indicated by a Z direction.

### EMBODIMENT

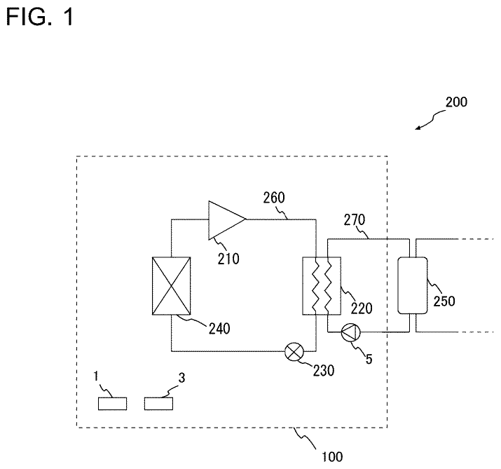

FIG. 1 is a circuit diagram illustrating a configuration of a heat-pump heat source apparatus 100 according to an embodiment. The heat-pump heat source apparatus 100 includes a compressor 210, a load-side heat exchanger 220, an expansion device 230, a heat-source-side heat exchanger 240, a refrigerant pipe 260, a water pipe 270, a water pump 5, a controller 1, and a transformer 3. It will be described with reference to FIG. 1 what configuration is applied to the heat-pump heat source apparatus 100 in a heat-pump water heater 200. In the heat-pump heat source apparatus 100, the compressor 210, the load-side heat exchanger 220, the expansion device 230, and the heat-source-side heat exchanger 240 are sequentially connected by the refrigerant pipe 260, whereby a heat-pump circuit is formed in which refrigerant such as carbon dioxide circulates. In addition, in the heat-pump heat source apparatus 100, the load-side heat exchanger 220 and the water pump 5 are sequentially connected to a hot-water storage tank 250 by the water pipe 270, whereby a water circuit is formed through which water flows. The heat-pump water heater 200 includes the heat-pump circuit and the water circuit. The heat-pump heat source apparatus 100 is part of the heat-pump water heater 200.

The compressor 210 sucks and compresses low-temperature and low-pressure gas refrigerant to change it into high-temperature and high-pressure gas refrigerant, and discharges the high-temperature and high-pressure gas refrigerant. The load-side heat exchanger 220 serves as a condenser. The load-side heat exchanger 220 causes heat exchange to be performed between refrigerant and water that flows through the water circuit. Specifically, heat is transferred from the refrigerant to the water, and the water is thus heated. The expansion device 230 reduces the pressure of high-pressure refrigerant, and regulates the pressure and flow rate of the refrigerant. The heat-source-side heat exchanger 240 causes heat exchange to be performed between air and refrigerant that flows through the heat-source-side heat exchanger 240. Specifically, the refrigerant receives heat from the air and thus evaporates. The heat-source-side heat exchanger 240 serves as an evaporator. In the heat-source-side heat exchanger 240, the refrigerant exchanges heat with, for example, outdoor air.

In the water circuit in the heat-pump water heater 200, the load-side heat exchanger 220, the hot-water storage tank 250, and the water pump 5 are sequentially connected by the water pipe 270. Water to be supplied as hot water circulates in the water circuit. The water to be supplied as hot water is stored in the hot-water storage tank 250. The water pump 5 pressurizes the water to be supplied as hot water and causes the pressurized water to circulate in the water circuit. Cold or hot water in a lower portion of the hot-water storage tank 250 is transferred by the water pump 5 to the load-side heat exchanger 220.

The above description refers to an example in which the heat-pump heat source apparatus 100 is used in the heat-pump water heater 200. However, the heat-pump heat source apparatus 100 is used to heat and cool water, and may thus be used as part of a heat-pump chiller.

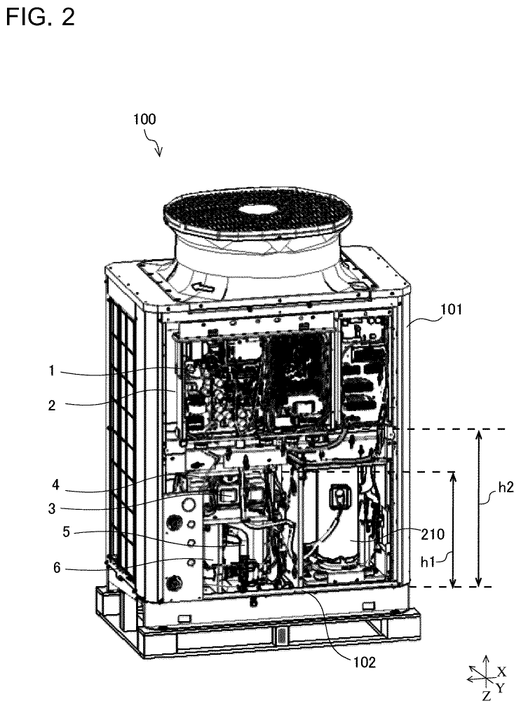

FIG. 2 is a perspective view illustrating an internal configuration of the heat-pump heat source apparatus 100 according to the embodiment. As illustrated in FIG. 2, the heat-pump heat source apparatus 100 includes the compressor 210, the controller 1, a controller box 2, the transformer 3, a transformer box 4, the water pump 5, and a water pump box 6 that are all housed in in a rectangular housing 101 that forms an outer shell of the heat-pump heat source apparatus 100. One of plates that form the sides of the housing 101 is removably provided as a removable plate, and in the state illustrated in FIG. 2, is removed from the housing 101. A face of the housing 101 of the heat-pump heat source apparatus 100 on which the removable plate is provided will be referred to as a “front face.” In the description, a front side of the housing 101 of the heat-pump heat source apparatus 100 refers to a side on which the removable plate is provided.

The controller 1 is provided with a microcomputer that includes a CPU, a ROM, a RAM, an I/O port, etc., and controls, for example, the compressor 210. The controller 1 is accommodated in the controller box 2. The transformer 3 is provided in the heat-pump heat source apparatus 100 to convert a voltage. A current obtained by conversion of the voltage by the transformer 3 is used to, for example, drive the compressor 210. The transformer 3 is accommodated in the transformer box 4. The water pump 5 causes water to circulate in the water circuit including the load-side heat exchanger 220. The water pump 5 is accommodated in the water pump box 6.

The water pump box 6 that accommodates the water pump 5 is provided on a bottom plate 102 of the housing 101. On the bottom plate 102 of the housing 101, the compressor 210 is provided alongside of the water pump box 6. Above the water pump box 6, the transformer box 4 that accommodates the transformer 3 is provided. Above the transformer box 4, the controller box 2 that accommodates the controller 1 is provided. The water pump box 6, the transformer box 4, and the controller box 2 do not overlap each other in the front-back direction. The water pump box 6 and the controller box 2 are provided on the front side in the interior of the housing 101 of the heat-pump heat source apparatus 100.

As illustrated in FIG. 2, height h1 is the total value of the height of the transformer box 4 and the height of the water pump box 6; and height h2 is a distance from the bottom plate 102 to a lower end of the controller box 2 in a height direction. In this case, the height h1 and the height h2 satisfy the relationship “h1<h2.”

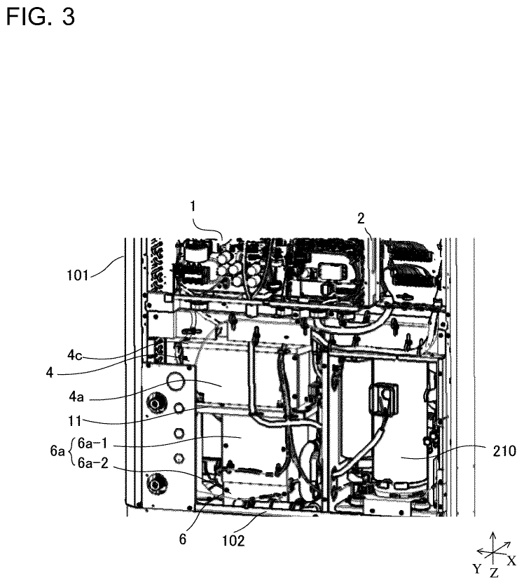

FIG. 3 is a perspective view illustrating an installation configuration of the water pump box 6, the transformer box 4, and the controller box 2 in Embodiment 1. The water pump box 6 has a front-face panel 6a that covers the front face. The front-face panel 6a has a first front-face panel 6a-1 and a second front-face panel 6a-2.

Above the water pump box 6, the transformer box 4 is provided such that at least part of the transformer box 4 overlaps the water pump box 6 as viewed in the up-down direction. A mount 11 is provided between the water pump box 6 and the transformer box 4. The mount 11 corresponds to a ceiling covering an upper face of the water pump box 6. The transformer box 4 is provided on the mount 11. The transformer box 4 includes a front-face panel 4a that covers a front face of the transformer box 4 and a top-face panel 4c that covers an upper face of the transformer box 4. The water pump box 6, the transformer box 4, and the mount 11 will be described later in detail.

Above the transformer box 4, the controller box 2 is provided in such a manner that at least part of the controller box 2 overlaps the transformer box 4 as viewed in the up-down direction. As illustrated in FIG. 3, other devices may be provided between the transformer box 4 and the controller box 2. Although not illustrated, the controller box 2 may be provided on the top-face panel 4c of the transformer box 4.

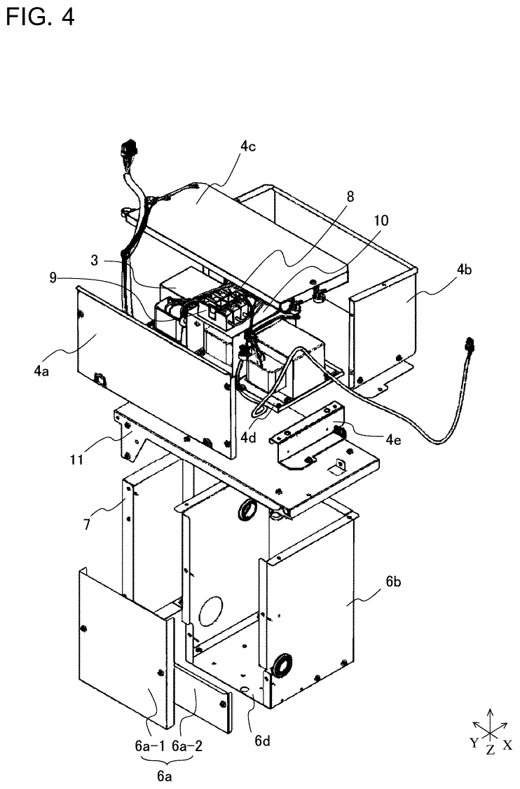

FIG. 4 is an exploded perspective view for explanation of the configuration of the water pump box 6 and the transformer box 4 according to Embodiment 1. In FIG. 4, an illustration of the water pump 5 is omitted. As illustrated in FIG. 4, the water pump box 6 includes a side-and-back-face panel 6b and a bottom-face panel 6d in addition to the first front-face panel 6a-1 and the second front-face panel 6a-2 described above.

The side-and-back-face panel 6b of the water pump box 6 forms left and right side faces and a back face of the water pump box 6. The bottom-face panel 6d forms a bottom face of the water pump box 6. The water pump 5 is provided on the bottom-face panel 6d. As illustrated in FIG. 4, opening portions may be provided in the side-and-back-face panel 6b to allow a water pipe (not illustrated) to be connected to the water pump 5 accommodated in the water pump box 6.

At the front face of the water pump box 6, the first front-face panel 6a-1 and the second front-face panel 6a-2 are provided. The second front-face panel 6a-2 is located at a lower position than the first front-face panel 6a-1. In an example illustrated in FIG. 4, the first front-face panel 6a-1 covers at least an upper half of the front face of the water pump box 6. The second front-face panel 6a-2 covers at least a lower quarter area of the front face of the water pump box 6. The first front-face panel 6a-1 and the second front-face panel 6a-2 are individually detachably attached to the side-and-back-face panel 6b. Since the first front-face panel 6a-1 and the second front-face panel 6a-2 are individually detachably attached, it suffices that only one of the first front-face panel 6a-1 and the second front-face panel 6a-2 is detached when needing to be subjected to maintenance, such as inspection or repair. In the following description, an inspection work or a repair work may be referred to as “maintenance.”

Even in the case where a component other than the water pump 5, for example, a pipe, is provided ahead of the front-face panel 6a of the water pump box 6, it may be possible to perform maintenance on the water pump 5 by detaching one of the first front-face panel 6a-1 and the second front-face panel 6a-2 without removing the above other component. Therefore, the component may be provided ahead of the front-face panel 6a of the water pump box 6. It should be noted that regarding the present embodiment, although it is descried above by way of example that two panels, that is, the first front-face panel 6a-1 and the second front-face panel 6a-2, are provided at the front face of the water pump box 6, three or more panels may be provided at the front face of the water pump box 6.

As illustrated in FIG. 4, the mount 11 is provided between the water pump box 6 and the transformer box 4. The mount 11 serves as a top-face panel of the water pump box 6. The transformer box 4 is provided on the mount 11. Since the transformer box 4 is provided on the mount 11, in the lateral direction, the mount 11 has a length greater than or equal to the length of the transformer box 4. Referring to FIG. 4, in the lateral direction, the length of the transformer box 4 is greater than that of the water pump box 6. Therefore, in the lateral direction, the length of the mount 11 is greater than that of the water pump box 6. Accordingly, the mount 11 partially projects from the water pump box 6. An end portion of the mount 11 that projects from the water pump box 6 in the lateral direction of the mount 11 is supported by a support leg 7. The other portion of the mount 11 that does not project from the water pump box 6 is supported by the water pump box 6.

The support leg 7 is provided on the bottom plate 102 of the housing 101. The height of the support leg 7 is equal to that of the water pump box 6. The support leg 7 has a face extending in the front-back direction of the heat-pump heat source apparatus 100, and supports a lower face of the mount 11 in the front-back direction. The support leg 7 as illustrated in FIG. 4 is formed in the shape of a rectangular tray, and supports the mount 11, while being upright. It should be noted that a plurality of support legs 7 may be provided.

The length of the mount 11 in the lateral direction may be increased to provide a space between the support leg 7 and the water pump box 6, regardless of the length of the transformer box 4 in the lateral direction. As the length of the mount 11 is increased, the length of the portion of the mount 11 that projects from the water pump box 6 is increased. Therefore, the distance between the water pump box 6 and the support leg 7 supporting the end portion of the mount 11 is also increased. Thus, a space is provided between the support leg 7 and the water pump box 6. This space can be used in the inspection work, maintenance, the repair work, or other work on the water pump 5. For example, the space between the support leg 7 and the water pump box 6 can be used as a work space to replace any of components attached to the pipe connected to the water pump 5, such as a thermal insulation cover, an antifreeze heater, and a thermistor, by a new one.

Although it is not illustrated, in the case where in the lateral direction, the length of the transformer box 4 is smaller than that of the water pump box 6, it suffices that in the lateral direction, the length of the mount 11 is set equal to that of the water pump box 6. In this case, the support leg 7 does not need to be provided.

The transformer box 4 is provided on the mount 11. The transformer box 4 includes a side-and-back-face panel 4b, a bottom-face panel 4d, and leg portions 4e in addition to the front-face panel 4a and the top-face panel 4c provided as described above. The front-face panel 4a and the top-face panel 4c of the transformer box 4 are individually detachably attached to the side-and-back-face panel 4b of the transformer box 4 as illustrated in FIG. 4. Even when it is difficult to detach the front-face panel 4a of the transformer box 4 because of the presence of components such as a power-supply wire and a pipe located ahead of to the front-face panel 4a, it is possible to detach the top-face panel 4c. It is therefore possible to check the interior of the transformer box 4 during maintenance. Accordingly, even when the components such as the power-supply wire and the pipe are located ahead of the front-face panel 4a of the transformer box 4, the maintenance is easily performed on the transformer 3.

The side-and-back-face panel 4b of the transformer box 4 forms the left and right side faces and the back face of the transformer box 4. The bottom-face panel 4d forms the bottom face of the transformer box 4. The transformer 3 is screwed and fixed on the bottom-face panel 4d. Referring to FIG. 4, three transformers 3 are arranged side by side in the lateral direction and accommodated in the transformer box 4. In the transformer box 4, a fuse 8, a fuse box 9, and a fuse base 10 are accommodated in addition to the three transformers 3. The three transformers 3, the fuse 8, the fuse box 9, and the fuse base 10 will be described later in detail.

The bottom-face panel 4d of the transformer box 4 is supported by two leg portions 4e. In the lateral direction of the transformer box 4, the bottom-face panel 4d is supported at its left-side end portion and right-side end portion by the respective leg portions 4e. Each of the leg portions 4e has a face extending in the front-back direction of the heat-pump heat source apparatus 100, and supports a lower surface of the bottom-face panel 4d in the front-back direction. It should be noted that FIG. 4 illustrates one of the leg portions 4e that is located on the right side, but does not illustrate the other leg portion 4e that is located on the left side.

Since the bottom-face panel 4d is supported by the leg portions 4e, a space is provided between the mount 11 and the bottom-face panel 4d. The front-face panel 4a of the transformer box 4 covers a space between the mount 11 and the top-face panel 4c of the transformer box 4. Thus, the space between the mount 11 and the bottom-face panel 4d of the transformer box 4 cannot be visually recognized as illustrated in FIG. 3. The leg portions 4e and the side-and-back-face panel 4b of the transformer box 4 are fixed to the mount 11, while overlapping each other.

The leg portions 4e and the side-and-back-face panel 4b may be fixed on the mount 11 by common screws, thereby fixing the transformer box 4 on the mount 11. In this case, the mount 11, the leg portions 4e, and the side-and-back-face panel 4b are formed to have screw holes. The screw holes of the leg portions 4e are aligned with the screw holes of the mount 11, and the screw holes of the side-and-back-face panel 4b are aligned with the screw holes of the leg portions 4e. Then, screws are screwed into the side-and-back face portion 4b from above, thereby fixing the leg portions 4e and the side-and-back-face panel 4b to the mount 11. As a result, the transformer box 4 is fixed to the mount 11.

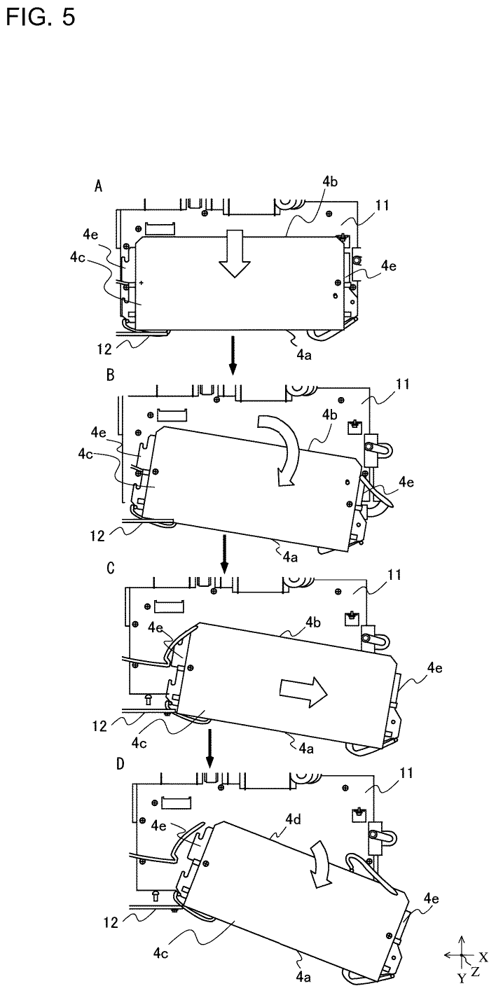

The transformer box 4 is detachably attached to the mount 11, with the transformers 3 accommodated in the transformer box 4. FIG. 5 is an explanatory view for the procedure for removal of the transformer box 4. FIG. 5 illustrates the transformer box 4 as viewed from above. Outlined arrows in FIG. 5 indicate the direction in which the transformer box 4 is moved. FIG. 5 illustrates an example in which a panel 12 is located on the front face of the transformer box 4 on the left side thereof. The following description is made on the assumption that the panel 12 is provided, for example, in such a manner as to cover at least part of the front face of the transformer box 4 on the left side thereof.

In the case where the transformer box 4 is screwed to the mount 11, first, the screws fixing the transformer box 4 to the mount 11 are all unscrewed. Then, with the transformer box 4 unscrewed from the mount 11, the transformer box 4 is pulled forward as illustrated in FIG. 5A. Then, as illustrated in FIG. 5B, while being slightly rotated in a clockwise direction, the transformer box 4 is pulled forward. Subsequently, the transformer box 4 is displaced rightward as illustrated in FIG. 5C to avoid contact with the panel 12 located on the front face of the transformer box 4 on the left side thereof. Then, as illustrated in FIG. 5D, while being gradually rotated in the clockwise direction, the transformer box 4 is pulled forward. It should be noted that FIG. 5 illustrates an example in which the panel 12 is located on the front face of the transformer box 4 on the left side thereof, and the transformer box 4 is thus rotated in the clockwise direction and pulled forward. In the case where the panel 12 is located on the front face of the transformer box 4 on the right side thereof, the transformer box 4 may be rotated in a counterclockwise direction and pulled forward.

As illustrated in FIGS. 5A to 5D, even when the panel 12 is located ahead of the front-face panel 4a of the transformer box 4, it is possible to pull and remove the transformer box 4 from the mount 11. It is therefore possible to provide the panel 12 ahead of the front-face panel 4a of the transformer box 4. Components other than the panel 12, such as the power-supply wire and the pipe, may be provided ahead of the front-face panel 4a of the transformer box 4.

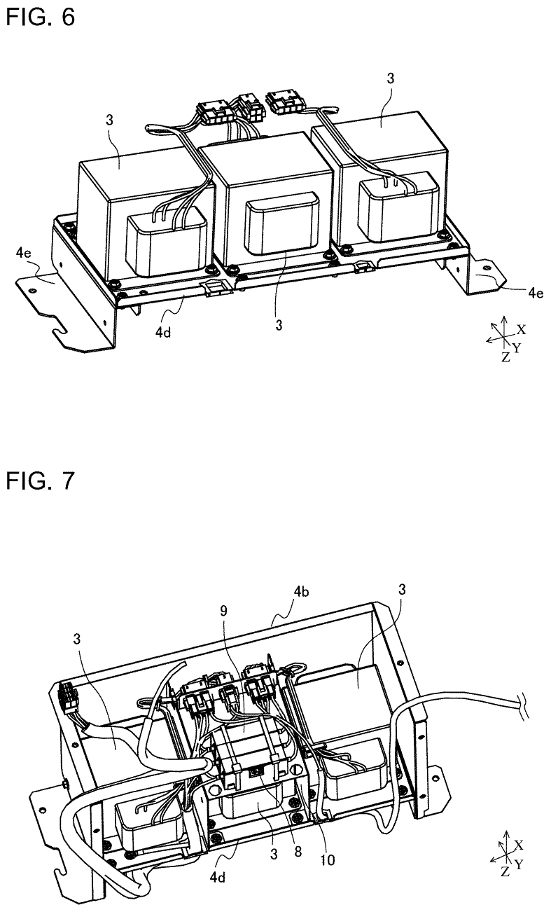

FIG. 6 is a perspective view for explanation of the arrangement of a plurality of transformers 3 according to Embodiment 1. The plurality of transformers 3 can be provided in the transformer box 4. Referring to FIG. 6, three transformers 3 are arranged side by side in the horizontal direction on the bottom-face panel 4d of the transformer box 4. The bottom-face panel 4d of the transformer box 4 is supported from its lower surface by the two leg portions 4e. Wires connected to the transformers 3 are accommodated along with the transformers 3 in the transformer box 4.

It should be noted that as described above, the transformer box 4 is provided on the mount 11. The mount 11 is supported by the water pump box 6 and the support leg 7. Thus, in the case where a plurality of transformers 3 are provided, even when the total length of the transformers 3 is greater than the length of the water pump box 6 in the lateral direction of the heat-pump heat source apparatus 100, the mount 11 can be supported by the water pump box 6 and the support leg 7. Therefore, the number of transformers 3 to be accommodated in the transformer box 4 is not limited by the length of the water pump box 6 in the lateral direction. The number of transformers 3 is not limited to three, and may be two or less, or four or more.

In the case where a plurality of transformers 3 are accommodated in the transformer box 4, by arranging the transformers 3 in the horizontal direction on the bottom-face panel 4d as illustrated in FIG. 6, it is possible to cause the transformer box 4 to have a smaller height than in the case where a plurality of transformers 3 are arranged in the up-down direction. Therefore, it is not necessary to increase the height of the housing 101 in order that the transformer box 4 be housed in the housing 101. In addition, in the case where the plurality of transformers 3 are arranged in the horizontal direction and accommodated in the transformer box 4, the center of gravity of the housing 101 is lowered. That is, by arranging the plurality of transformers 3 in the horizontal direction and then accommodating the plurality of transformers 3 in the transformer box 4, it is possible to set the height of the housing 101 such that the housing 101 is not too high, and to lower the center of gravity of the housing 101. Thus, the housing 101 is stabilized.

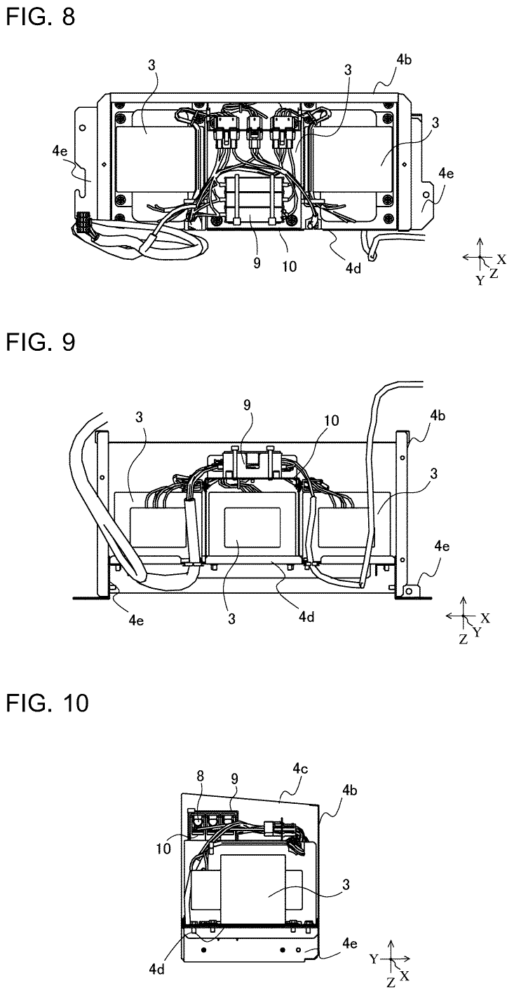

Next, the fuse 8, the fuse box 9, and the fuse base 10 that are accommodated in the transformer box 4 will be described with reference to FIGS. 7 to 10. FIG. 7 is a perspective view illustrating an internal configuration of the transformer box 4 according to the embodiment. FIG. 7 illustrates the transformer box 4, with its front-face panel 4a and top-face panel 4c removed from the transformer box 4. FIG. 8 is a plan view of the transformer box 4 that is in the state illustrated in FIG. 7. FIG. 9 is a front view of the transformer box 4 that is in the state illustrated in FIG. 7. FIG. 10 is a transparent side view of the transformer box 4 that is in the state illustrated in FIG. 7.

As illustrated in FIGS. 7 to 10, the fuse 8, the fuse box 9, and the fuse base 10 are accommodated in the transformer box 4. As illustrated in FIG. 7, the fuse base 10 is provided on the bottom-face panel 4d of the transformer box 4 in such a manner as to cover left and right sides and a top side of a single transformer 3. The fuse box 9 is provided on a top side of the fuse base 10. The fuse 8 is accommodated in the fuse box 9. A plurality of fuses 8 may be accommodated in the fuse box 9. The fuse 8 and each of the transformers 3 are connected by wires in the transformer box 4. As illustrated in FIGS. 7 to 10, the wires can be branched off using terminals provided in the fuse box 9. It is therefore possible to reduce the number of terminal blocks to be used.

The fuse base 10 can be used as a fixing tool to fix joint connectors for the wires. On a back side of the fuse base 10, the joint connectors are provided. The fuse box 9 is provided on a front side of the fuse base 10. To be more specific, the fuse box 9 is provided at an upper portion of the front side of the transformer 3. The wires from the transformers 3 and the fuse 8 are connected to the joint connectors on a back side of the fuse base 10. The above space between the mount 11 and the bottom-face panel 4d of the transformer box 4 can be used as a space for accommodation of the wires connected to the transformers 3 and to the fuse 8 as illustrated in FIG. 9. It should be noted that it is allowable that the fuse box 9 is not located in the forefront of the fuse base 10 and the joint connectors are not located on the back side of the fuse base 10. The joint connectors may be provided on the front side of the fuse box 9.

As illustrated in FIGS. 7 to 10, the fuse box 9 is located on the front side of the inside of the transformer box 4. Thus, after the front-face panel 4a of the transformer box 4 is detached, the fuse 8 accommodated in the fuse box 9 can be easily replaced by a new one. Since the fuse 8 is provided in the transformer box 4, inspection, maintenance, repair, or other work can be performed on each of the transformers 3 in the transformer box 4.

As described above, the front-face panel 4a and the top-face panel 4c of the transformer box 4 are individually detachably attached to the transformer box 4. Furthermore, the transformer box 4 is detachably attached to the mount 11, with the transformers 3 accommodated in the transformer box 4. Thus, even in the case where components such as the panel 12, the power-supply wire, and the pipe are provided ahead of the front-face panel 4a of the transformer box 4, after the front-face panel 4a or the top-face panel 4c is detached, with the transformer box 4 kept fixed to the mount 11, or the transformer box 4 is removed from the mount 11 as needed, it is possible to perform inspection, maintenance, repair, or other work on each of the transformers 3 and the fuse 8.

The fuse 8 is accommodated in the transformer box 4, and the controller 1 is accommodated in the controller box 2. Thus, the fuse 8 is not easily affected by heat of the controller 1, thereby reducing the likelihood that the temperature of the fuse 8 will rise. It is therefore possible to reduce occurrence of a problem that would be caused by rising of the temperature of the fuse 8.

Furthermore, although it is not illustrated, the transformers 3 may use wire connectors having different shapes. By causing the wire connectors to have different shapes, it is possible to reduce occurrence of a mistake in connection of the wires in the transformer box 4.

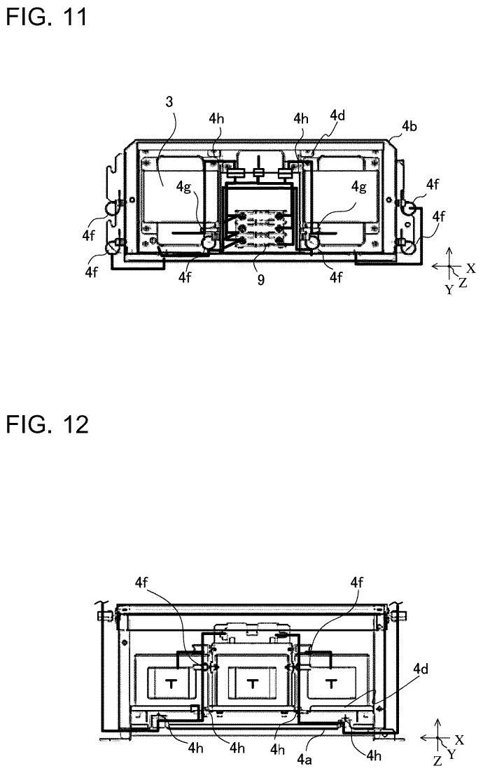

Next, bundling of the wires in the transformer box 4 will be described with reference to FIGS. 11 and 12. FIG. 11 is a plan view illustrating bundling of the wires in the transformer box 4 according to the embodiment. FIG. 12 is a front view illustrating bundling of the wires in the transformer box 4 according to the embodiment.

As illustrated in FIGS. 11 and 12, in the transformer box 4, cable straps 4f, wire saddles 4g, and edge saddles 4h are provided to bundle the wires. A plurality of cable straps 4f, a plurality of wire saddles 4g, and a plurality of edge saddles 4h are provided. Not all of the cable straps 4f, the wire saddles 4g, and the edge saddles 4h provided in the transformer box 4 need to be used in bundling of the wires. As needed, the cable straps 4f, the wire saddles 4g, and the edge saddles 4h may be used to bundle the wires.

As illustrated in FIG. 11, each of the cable straps 4f has a ring shape and bundles a plurality of wires together. Some of the cable straps 4f are provided at the outside of the transformer box 4 to bundle wires extending from the interior of the transformer box 4 to the outside of the transformer box 4.

Each of the wire saddles 4g bundles a plurality of wires together. The shape of the wire saddle 4g is not limited to a specific one. For example, the wire saddle 4g has a rectangular or circular shape and a slit through which wires can be inserted.

Each of the edge saddles 4h bundles a plurality of wires together. The edge saddle 4h prevents the wires that pass through the front-face panel 4a and the bottom-face panel 4d of the transformer box 4 from being damaged by a corner portion, an edge portion, and other portions. For example, in the case where a cut for passage of wires is provided in the lower end portion of the front-face panel 4a of the transformer box 4, the edge saddle 4h is provided in the cut.

As described above, in the present embodiment, the heat-pump heat source apparatus 100 includes: the housing 101 including the bottom plate 102; the water pump box 6 provided on the front side of the bottom plate 102 to accommodate the water pump 5; the transformer box 4 provided above the water pump box 6 to accommodate the transformer 3; and the controller box 2 provided above the transformer box 4 to accommodate the controller 1.

In the above configuration, the controller 1 and the transformer 3 are provided above the water pump box 6. Thus, even if a water leak occurs in the housing 101 of the heat-pump heat source apparatus 100, the controller 1 and the transformer 3 are prevented from being submerged or immersed in water.

The water pump box 6, the transformer box 4, and the controller box 2 are arranged in the housing 101 in the up-down direction of the heat-pump heat source apparatus 100. Therefore, the water pump box 6, the transformer box 4, and the controller box 2 do not overlap each other in the front-back direction of the heat-pump heat source apparatus 100. It is therefore possible to individually subject the water pump 5, the transformer 3, and the controller 1 to inspection, maintenance, repair, or other work. In addition, when the water pump 5, the transformer 3, and the controller 1 is each subjected to inspection, maintenance, repair, or other work, each of the water pump 5, the transformer 3, and the controller 1 does not interfere with the above work performed on the other components. In other words, the water pump 5, the transformer 3, and the controller 1 do not mutually affect their serviceability.

In the case where a transformer is provided on an upper portion of the interior of a housing in order to prevent the transformer being submerged or immersed in the water, the center of gravity of the housing may be raised. By contrast, in the present embodiment, the transformer 3 is provided between the water pump box 6 and the controller box 2. To be more specific, in the housing 101, the water pump 5 and the transformer 3 are provided in lower regions than the controller box 2, and it is therefore possible to lower the center of gravity of the housing 101.

Furthermore, in the heat-pump heat source apparatus 100 according to the present embodiment, the transformer box 4 is provided on a ceiling of the water pump box 6. The ceiling of the water pump box 6 corresponds to the mount 11 provided between the water pump box 6 and the transformer box 4. To be more specific, the mount 11 corresponding to the ceiling of the water pump box 6 is provided between the water pump box 6 and the transformer box 4, the transformer box 4 is provided on the mount 11, and the bottom-face panel 4d of the transformer box 4 is fixed to the mount 11 by screws. In this configuration, the transformer box 4 that accommodates the transformer 3 is provided on the mount 11 corresponding to the ceiling of the water pump box 6. In general, in the case where a transformer is provided on the back side in the interior of the housing, the workability of inspection, maintenance, repair, or other work on the transformer is worsened. In the present embodiment, the water pump box 6 is provided on the front side of the bottom plate 102, and the transformer box 4 provided on the ceiling of the water pump box 6 is thus also located on the front side of the housing 101. Accordingly, the workability of inspection, maintenance, repair, or other work on the transformer 3 accommodated in the transformer box 4 is not worsened. Furthermore, since the transformer box 4 is fixed to the mount 11 corresponding to the ceiling of the water pump box 6, it is possible to reduce the number of components in the housing 101 and efficiently use the internal space of the housing 101.

The heat-pump heat source apparatus 100 according to the present embodiment includes the support leg 7 that is provided alongside of the water pump box 6 on the bottom plate 102 and that supports the transformer box 4 from below. Thus, even in the case where the length of the transformer box 4 is greater than the length of the water pump box 6 in the lateral direction of the heat-pump heat source apparatus 100, it is possible to provide the transformer box 4 above the water pump box 6.

In the heat-pump heat source apparatus 100 according to the present embodiment, a space is provided between the support leg 7 and the water pump box 6. Thus, the space between the support leg 7 and the water pump box 6 can be used for inspection, maintenance, repair, or other work on the water pump 5.

The water pump box 6 in the heat-pump heat source apparatus 100 according to the present embodiment includes the front-face panel 6a that is detachably attached to the water pump box 6 and that covers the front face of the water pump box 6. The front-face panel 6a of the water pump box 6 includes the first front-face panel 6a-1, and the second front-face panel 6a-2 provided on the lower side of the first front-face panel 6a-1. With this configuration, even in the case where other components such as a pipe are provided on the front face of the water pump box 6, it is possible to perform inspection, maintenance, repair, or other work on the water pump 5 accommodated in the water pump box 6 by removing either one or both of the first front-face panel 6a-1 and the second front-face panel 6a-2.

The transformer box 4 in the heat-pump heat source apparatus 100 according to the present embodiment accommodates a plurality of transformers 3, and the plurality of transformers 3 are arranged side by side in the horizontal direction and accommodated in the transformer box 4. Thus, it is not necessary to increase the height of the transformer box 4. Therefore, in addition to an advantage in which the height of the transformer box 4 does not need to be increased, it is possible to lower the center of gravity of the housing 101.

The transformer box 4 in the heat-pump heat source apparatus 100 according to the present embodiment includes the fuse box 9 and the fuse 8 accommodated in the fuse box 9, and the transformers 3 and the fuse 8 are connected in the transformer box 4. Therefore, in the transformer box 4, it is possible to perform inspection, maintenance, repair, or other work on the transformers 3. Since the fuse 8 and the controller 1 are isolated from each other by the transformer box 4 and the controller box 2, the fuse 8 is not easily affected by heat of the controller 1, thereby reducing rising of the temperature of the fuse 8 and also occurrence of a failure in the fuse 8. It is therefore possible to reduce occurrence of a failure in the heat-pump heat source apparatus 100.

In the transformer box 4 in the heat-pump heat source apparatus 100 according to the present embodiment, the fuse base 10 is provided above the transformers 3, and the fuse box 9 is provided on the fuse base 10. The fuse base 10 can also be used as a fixing tool to fix joint connectors for wires of the transformers 3 and the fuse 8 that are accommodated in the transformer box 4. It is therefore possible to reduce complication of wiring in the transformer box 4.

In the transformer box 4 in the heat-pump heat source apparatus 100 according to the present embodiment, on the fuse base 10, the fuse box 9 is located on the front side of the transformer box 4. It is therefore possible to easily replace the fuse 8 accommodated in the fuse box 9 by a new one, by removing the front-face panel 4a of the transformer box 4.

The transformer box 4 in the heat-pump heat source apparatus 100 according to the present embodiment includes the top-face panel 4c and the detachable front-face panel 4a that are detachably attached. It is therefore possible to perform inspection, maintenance, repair, or other work on the transformers 3 accommodated in the transformer box 4, by removing either one or both of the top-face panel 4c and the front-face panel 4a.

1. A heat-pump heat source apparatus comprising:
a housing including a bottom plate;
a water pump box provided on a front side on the bottom plate in the housing, the water pump box accommodating a water pump;
a transformer box provided above the water pump box in the housing, the transformer box accommodating a transformer; and
a controller box provided above the transformer box in the housing, the controller box accommodating a controller.

2. The heat-pump heat source apparatus of claim 1, wherein the transformer box is provided on a ceiling of the water pump box.

3. The heat-pump heat source apparatus of claim 1, wherein
a mount is provided between the water pump box and the transformer box, the mount corresponding to a ceiling of the water pump box, and
the transformer box is provided on the mount and includes a bottom-face panel that is fixed to the mount by screws.

4. The heat-pump heat source apparatus of claim 1, further comprising a support leg that is provided on the bottom plate and alongside of the water pump box, the support leg supporting the transformer box from below.

5. The heat-pump heat source apparatus of claim 4, wherein a space is provided between the support leg and the water pump box.

6. The heat-pump heat source apparatus of claim 1, wherein the water pump box includes a front-face panel that is detachably attached to the water pump box and covers a front face of the water pump box.

7. The heat-pump heat source apparatus of claim 6, wherein the front-face panel of the water pump box includes
a first front-face panel, and
a second front face panel provided on a lower side than the first front-face panel.

8. The heat-pump heat source apparatus of claim 1, wherein
the transformer box accommodates a plurality of the transformers, and
the plurality of the transformers are accommodated in the transformer box and arranged side by side in a horizontal direction.

9. The heat-pump heat source apparatus of claim 1, further comprising:
a fuse box accommodated in the transformer box; and
a fuse accommodated in the fuse box,
wherein the transformer and the fuse are connected in the transformer box.

10. The heat-pump heat source apparatus of claim 9, wherein
a fuse base is provided above the transformer in the transformer box, and
the fuse box is provided on the fuse base.

11. The heat-pump heat source apparatus of claim 10, wherein on the fuse base, the fuse box is located on a front side of the transformer box.

12. The heat-pump heat source apparatus of claim 1, wherein the transformer box includes
a detachable top-face panel, and
a detachable front-face panel.
